(19) United States
(12) Patent Application Publication
(10) Pub. No.: US 2012/0141657 A1
(43) Pub. Date: Jun. 7, 2012

(54) APPARATUS AND METHOD FOR ADJUSTING THE TRACK OF A GRANULE-COATED SHEET

(75) Inventor: David P. Aschenbeck, Newark, OH (US)

(73) Assignee: OWENS CORNING INTELLECTUAL CAPITAL, LLC, Toledo, OH (US)

(21) Appl. No.: 12/959,531

(22) Filed: Dec. 3, 2010

(51) Int. Cl. C23C 16/52; B05C 19/04

(52) U.S. Cl. 427/8; 118/308

(57) ABSTRACT

A method for adjusting the track of a granule-coated sheet includes moving a granule-coated sheet around a drum. The granule-coated sheet includes first granules. A track of the granule-coated sheet is sensed at the drum. A first signal is generated when the granule-coated sheet has moved off a pre-designated track. Second granules are applied to a lane portion of the granule-coated sheet prior to the drum in response to the first signal. The second granules make the granule-coated sheet thicker in the lane portion relative to a thickness of the granule-coated sheet outside the lane portion.

### BACKGROUND

This invention relates to asphalt-based roofing materials. More particularly, this invention relates to methods and apparatus for adjusting the track of a granule-coated sheet. Asphalt-based roofing materials, such as roofing shingles, roll roofing, and commercial roofing, are installed on the roofs of buildings to provide protection from the elements, and to give the roof an aesthetically pleasing appearance. Typically, the roofing material is constructed of a substrate such as a glass fiber mat or an organic felt, an asphalt coating on the substrate, and a surface layer of granules embedded in the asphalt coating.

A common method for the manufacture of asphalt shingles is the production of a continuous sheet of asphalt material followed by a shingle cutting operation which cuts the material into individual shingles. In the production of asphalt sheet material, either a glass fiber mat or an organic felt mat is passed through a coater containing hot liquid asphalt to form a tacky, asphalt-coated sheet. Subsequently, the hot asphalt-coated sheet is passed beneath one or more granule applicators which discharge protective and decorative surface granules onto portions of the asphalt sheet material.

In the manufacture of colored shingles, two types of granules are typically employed. Headlap granules are granules of relatively low cost used for the portion of the shingle which will be covered on the roof. Colored granules or prime granules are of relatively higher cost and are applied to the portion of the shingle that will be exposed and visible on the roof.

To provide a color pattern of pleasing appearance, the colored portion of the shingles may be provided with areas of different colors. Usually the shingles have a background color and a series of granule deposits of different colors or different shades of the background color. A common method for manufacturing the shingles is to discharge blend drops onto spaced areas of the tacky, asphalt-coated sheet. Background granules are then discharged onto the sheet and adhere to the tacky, asphalt-coated areas of the sheet between the granule deposits formed by the blend drops. The background granules are applied to the extent that the asphalt-coated sheet becomes completely covered with granules, thereby defining a granule-coated sheet. The granule-coated sheet is then turned around a slate drum to press the granules into the asphalt coating and to temporarily invert the sheet.

The term “blend drop,” as used herein, refers to the flow of granules of different colors or different shades of color (with respect to the background color) that is discharged from a granule blend drop applicator onto the asphalt-coated sheet. The patch or assemblage of the blend drop granules on the asphalt-coated sheet is also referred to as the “blend drop.”

One of the problems with conventional asphalt shingle manufacturing equipment is that the granule-coated sheet can wander or move laterally as it moves across the slate drum. The above notwithstanding, there remains a need in the art for an improved method of ensuring that the granule-coated sheet remains on its desired track and does not wander.

### SUMMARY OF THE INVENTION

The present application describes various embodiments of a method for adjusting the track of a granule-coated sheet. One embodiment of the method for adjusting the track of a granule-coated sheet includes moving a granule-coated sheet around a drum. The granule-coated sheet includes first granules. A track of the granule-coated sheet is sensed at the drum. A first signal is generated when the granule-coated sheet has moved off a pre-designated track. Second granules are applied to a lane portion of the granule-coated sheet prior to the drum in response to the first signal. The second granules make the granule-coated sheet thicker in the lane portion relative to a thickness of the granule-coated sheet outside the lane portion.

In another embodiment, a granule applicator includes a granule hopper defining a granule outlet. A gate is movably mounted relative to the hopper. The gate is movable between a plurality of first open positions wherein granules may flow out of the granule outlet. The gate is also pivotally movable relative to the granule hopper between any of the plurality of first open positions and a plurality of pivoted positions.

In another embodiment, a method for adjusting the track of a granule-coated sheet includes discharging granules from a granule dispenser on to an asphalt-coated sheet to define a granule-coated sheet. The granule-coated sheet is moved around a drum and a track of the granule-coated sheet is sensed at the drum. A first signal is generated when the granule-coated sheet has moved off a pre-designated track. The amount of granules discharged from the granule dispenser on to a lane portion of the granule-coated sheet is increased in response to the first signal. The increased amount of granules make the granule-coated sheet thicker in the lane portion relative to a thickness of the granule-coated sheet outside the lane portion.

Other advantages of the method for adjusting the track of a granule-coated sheet will become apparent to those skilled in the art from the following detailed description, when read in light of the accompanying drawings.

### BRIEF DESCRIPTION OF THE DRAWINGS

A complete appreciation of the invention and the many embodiments thereof will be readily obtained as the same becomes better understood by reference to the following detailed description when considered in connection with the accompanying drawings.

FIG. 1 is a schematic view in elevation of an apparatus for manufacturing an asphalt-based roofing material according to the invention.

FIG. 2 is a schematic side elevation view of a first embodiment of the tracking granule applicator illustrated in FIG. 1.

FIG. 3 is an enlarged schematic plan view of a portion of the asphalt-coated sheet illustrated in FIG. 1, showing the two of the tracking granule applicators illustrated in FIGS. 1 and 2.

FIG. 4 is a schematic plan view of a second embodiment of a tracking granule applicator.

FIG. 5 is a schematic side elevation view of the second embodiment of the tracking granule applicator illustrated in FIG. 4.

FIG. 6 is a schematic plan view of the gate of the second embodiment of a tracking granule applicator illustrated in FIG. 4, showing the gate in a second position.

### DETAILED DESCRIPTION

The present invention will now be described with occasional reference to the illustrated embodiments of the invention. This invention may, however, be embodied in different forms and should not be construed as limited to the embodiments set forth herein, nor in any order of preference. Rather, these embodiments are provided so that this disclosure will be more thorough, and will convey the scope of the invention to those skilled in the art.

Unless otherwise defined, all technical and scientific terms used herein have the same meaning as commonly understood by one of ordinary skill in the art to which this invention belongs. The terminology used in the description of the invention herein is for describing particular embodiments only and is not intended to be limiting of the invention. As used in the description of the invention and the appended claims, the singular forms “a,” “an,” and “the” are intended to include the plural forms as well, unless the context clearly indicates otherwise.

Unless otherwise indicated, all numbers expressing quantities of ingredients, properties such as molecular weight, reaction conditions, and so forth as used in the specification and claims are to be understood as being modified in all instances by the term “about.” Accordingly, unless otherwise indicated, the numerical properties set forth in the specification and claims are approximations that may vary depending on the desired properties sought to be obtained in embodiments of the present invention. Notwithstanding that the numerical ranges and parameters setting forth the broad scope of the invention are approximations, the numerical values set forth in the specific examples are reported as precisely as possible. Any numerical values, however, inherently contain certain errors necessarily resulting from error found in their respective measurements.

As used in the description and the appended claims, the phrase “asphalt coating” is defined as any type of bituminous material suitable for use on a roofing material, such as asphalts, tars, pitches, or mixtures thereof. The asphalt may be either manufactured asphalt produced by refining petroleum or naturally occurring asphalt. The asphalt coating may include various additives and/or modifiers, such as inorganic fillers or mineral stabilizers, organic materials such as polymers, recycled streams, or ground tire rubber. Preferably, the asphalt coating contains asphalt and an inorganic filler or mineral stabilizer.

As used in the description and the appended claims, the term “wander” is defined as any lateral movement; i.e., movement transverse to the machine direction 13, of the granule-coated sheet 28 relative to the slate drum 30 as the granule-coated sheet 28 moves across the slate drum 30.

Laminated composite shingles, such as asphalt shingles, are a commonly used roofing product. Asphalt shingle production generally includes feeding a base material from an upstream roll and coating it first with a roofing asphalt material, then a layer of granules. The base material is typically made from a fiberglass mat provided in a continuous shingle membrane or sheet. It should be understood that the base material can be any suitable support material.

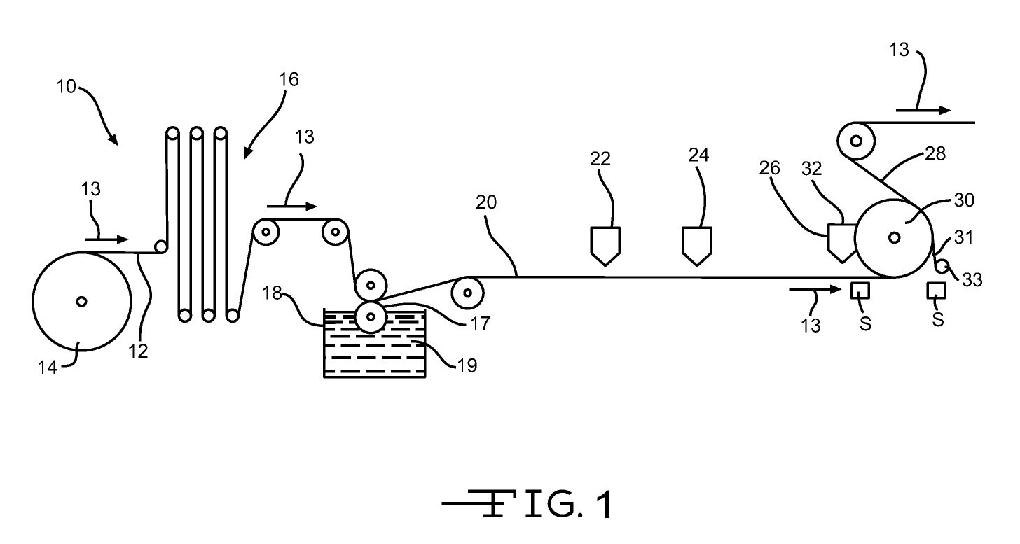

Referring now to the drawings, there is shown in FIG. 1 an apparatus 10 for manufacturing an asphalt-based roofing material, and more particularly for applying granules onto an asphalt-coated sheet. The illustrated manufacturing process involves passing a continuous sheet of substrate or shingle mat 12 in a machine direction 13 through a series of manufacturing operations. The sheet usually moves at a speed of at least about 200 feet/minute (61 meters/minute), and typically at a speed within the range of between about 450 feet/minute (137 meters/minute) and about 620 feet/minute (244 meters/minute). However, other speeds may be used.

In a first step of the manufacturing process, the continuous sheet of shingle mat 12 is payed out from a roll 14. The shingle mat 12 may be any type known for use in reinforcing asphalt-based roofing materials, such as a nonwoven web of glass fibers. Alternatively, the substrate may be a scrim or felt of fibrous materials such as mineral fibers, cellulose fibers, rag fibers, mixtures of mineral and synthetic fibers, or the like.

The sheet of shingle mat 12 is passed from the roll 14 through an accumulator 16. The accumulator 16 allows time for splicing one roll 14 of substrate to another, during which time the shingle mat 12 within the accumulator 16 is fed to the manufacturing process so that the splicing does not interrupt manufacturing.

Next, the shingle mat 12 is passed through a coater 18 where a coating of hot, melted asphalt 19 is applied to the shingle mat 12 to form an asphalt-coated sheet 20. The asphalt coating 19 may be applied in any suitable manner. In the illustrated embodiment, the shingle mat 12 contacts a roller 17, which is in contact with the supply of hot, melted asphalt 19. The roller 17 completely covers the shingle mat 12 with a tacky coating of asphalt 19. However, in other embodiments, the asphalt coating 19 could be sprayed on, rolled on, or applied to the shingle mat 12 by other means. Typically the asphalt coating is highly filled with a ground mineral filler material, amounting to at least about 42 percent by weight of the asphalt/filler combination. In one embodiment, the asphalt coating 19 is in a range from about 350° F. to about 400° F. In another embodiment, the asphalt coating 19 may be more than 400° F. or less than 350° F. The shingle mat 12 exits the coater 18 as an asphalt-coated sheet 20. The asphalt coating 19 on the asphalt-coated sheet 20 remains hot.

The asphalt-coated sheet 20 is passed beneath a first granule applicator. In the illustrated embodiment, the first granule applicator is a blend drop applicator, shown schematically at 22. The blend droop applicator 22 applies prime or blend drop granules 21 to the overlay prime granule lanes or lane portions of the asphalt-coated sheet 20, such as the lanes PO1 and PO2 described below, to define blend drops 34. Prime granules may also be applied to the underlay prime granule lanes, such as the lanes PU1 and PU2 also described below. Although only one blend drop applicator 22 is shown, it will be understood that several blend drop applicators 22 may be used. Alternatively, the blend drop applicator 22 may be adapted to supply several streams of blend drops, or blend drops of different colors, shading, or size to the asphalt-coated sheet 20, thereby defining a granule-coated sheet 28.

The granule-coated sheet 28 is then passed beneath a second granule applicator. In the illustrated embodiment, the second granule applicator is a tracking granule applicator, shown schematically at 24 and described in its various embodiments below. The tracking granule applicator 24 applies granules to the granule-coated sheet 28 to selectively increase the thickness of the granule coating at a selected portion of the granule-coated sheet 28.

The granule-coated sheet 28 is then passed beneath a third granule applicator. In the illustrated embodiment, the third granule applicator is a backfall granule applicator 26, for applying additional granules, such as shadow granules to form a shadow strip, background granules, and/or headlap granules 35 onto the granule-coated sheet 28.

The background granules headlap granules are applied to the extent that the granule-coated sheet 28 becomes completely covered with granules. The granule-coated sheet 28 is then turned around a slate drum 30 on a pre-designated track to press the granules into the asphalt coating and to temporarily invert the granule-coated sheet 28. Such inverting of the granule-coated sheet 28 causes any excess granules to drop off the granule-coated sheet 28 on the backside of the slate drum 30. The excess granules are collected by a hopper 32 of the backfall granule applicator 26 and may be reused.

If desired, release tape 31 may be applied to the backside of the headlap granule lanes H1 and H2 of the granule-coated sheet 28. For example, as shown in FIG. 1, release tape 31 may be applied from an applicator or roll 33 as the granule-coated sheet 28 moves around the slate drum 30.

As shown in FIG. 1, the hopper 32 is positioned on the backside of the slate drum 30. Sensors S may be provided adjacent the slate drum 30 either upstream, downstream, or both upstream and downstream of the slate drum 30 to detect undesirable lateral movement of the granule-coated sheet 28 as the granule-coated sheet 28 moves across the slate drum 30. The sensors S may be any desired type of sensor, such as a photo eye, a laser, a line camera, or edge detector. Alternatively, any sensor that can monitor the longitudinal edges of the granule-coated sheet 28 relative to the outside edges of the slate drum 30 may be used.

The granule-coated sheet 28 is then cooled, cut, and packaged in any suitable manner (not shown). The cooling cutting and packaging operations are well known in the art.

In the manufacture of laminated shingles, it is important to maintain lateral alignment between the granules deposited by the granule applicators, such as the blend drop applicators 22 and the longitudinal edges of the granule-coated sheet 28. It is also important to maintain lateral alignment between the applied tape, such as the release tape 31, and the longitudinal edges of the granule-coated sheet 28. Known methods of laterally aligning granules or tape, such as by laterally moving the granule or blend drop applicators 22 and/or the tape applicator 33, requires multiple and independent sensors and/or tracking mechanisms. Alternatively, the slate drum 30 could be moved, such as by rotating in a horizontal plane to reposition the granule-coated sheet 28. Additional rolls may also be required to return a misaligned granule-coated sheet 28 to a desired position. The additional equipment and the mechanism required to move the slate drum 30 would therefore be very complex.

The embodiments of the tracking granule applicator 24 described below advantageously allow the relative lateral position of the granule-coated sheet 28 to be controlled by selectively adding additional granules to shift the lateral or cross-machine distribution of granules on the granule-coated sheet 28.

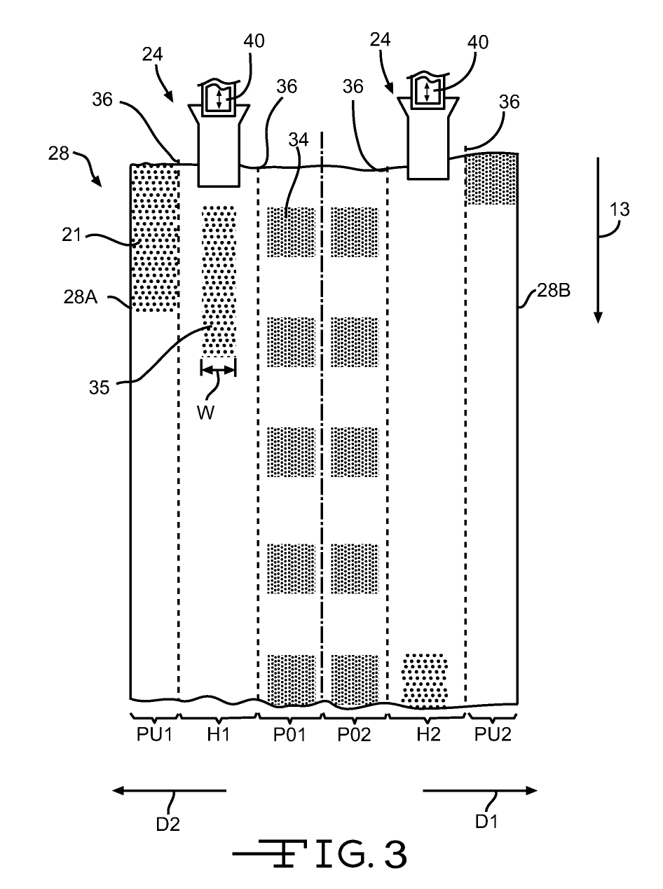

A portion of an exemplary granule-coated sheet 28 is shown in FIG. 3 after application of the prime granules 21 and/or the blend drops 34. As shown, the granule-coated sheet 28 has a first longitudinal side 28A (the left side when viewing FIG. 3) and a second longitudinal side 28B (the right side when viewing FIG. 3) and may be formed in an apparatus 10 for forming multiple shingles. For example, the granule-coated sheet 28 may be formed in an apparatus 10 for forming a plurality of shingles, such as two, three, or four shingles. The background granules may include granules of different colors and/or types, such as headlap granules and prime granules, as described in detail above. In the embodiment illustrated in FIG. 3, the granule-coated sheet 28 includes six different lanes. In the embodiment of the granule-coated sheet 28 illustrated in FIG. 3, two headlap granule lanes H1 and H2, two overlay prime granule lanes PO1 and PO2, and two underlay prime granule lanes PU1 and PU2, are shown. In the embodiment of the granule-coated sheet 28 shown in FIGS. 3 & 4, the lanes PU1, H1, and PO1 define a first longitudinal half of the granule-coated sheet 28, and the lanes PU2, H2, and PO2 define a second longitudinal half of the granule-coated sheet 28

Interface lines 36 extend in the machine direction 13 and define a boundary between two granule lanes having a different color and/or type of granule. In the illustrated embodiments, the interface lines 36 are defined between adjacent headlap granule lanes and prime granule lanes, such as between the headlap granule lane H1 and the prime granule lane PO1.

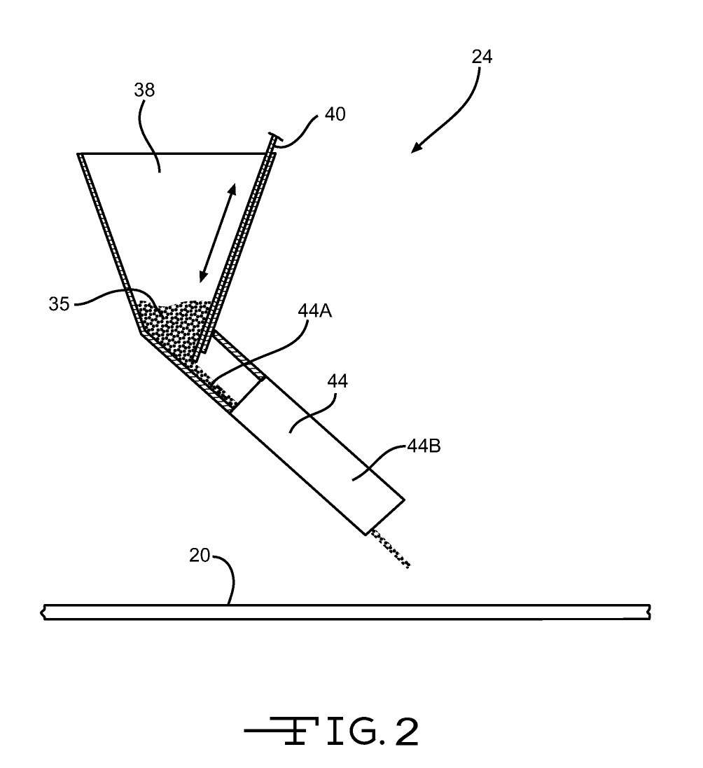

As shown schematically in FIG. 2, a first embodiment of the tracking granule applicator 24 may include a hopper 38. The hopper 38 receives and temporarily stores granules, such as headlap granules 35 from a source of granules (not shown). Alternatively, granules 35 may be moved into the hopper 38 by other suitable means. For example, the granules 35 may be moved into the hopper 38 through a gravity-feed device, such as a chute or tube (not shown). The tracking granule applicator 24 may also include a mechanism for metering and delivering the granules 35. In the illustrated embodiment, the mechanism for metering and delivering the granules 35 includes a movable gate 40 for selectively releasing granules 35 into a chute 44. The chute 44 guides the granules 35 outwardly and downwardly from the hopper 38 to the asphalt-coated sheet 20.

The illustrated chute 44 has a substantially flat lower surface 44A, and may include side walls 44B. Alternatively, the chute 44 may have other shapes, such as a substantially curved cross-sectional shape. The chute 44 extends outwardly and down-stream toward the upwardly facing surface of the asphalt-coated sheet 20.

It will be understood that the tracking granule applicator 24 described above is not required, and that any other desired granule dispenser may be provided. Examples of other suitable granule dispensers include a hopper having a fluted roll, and a vibratory feeder.

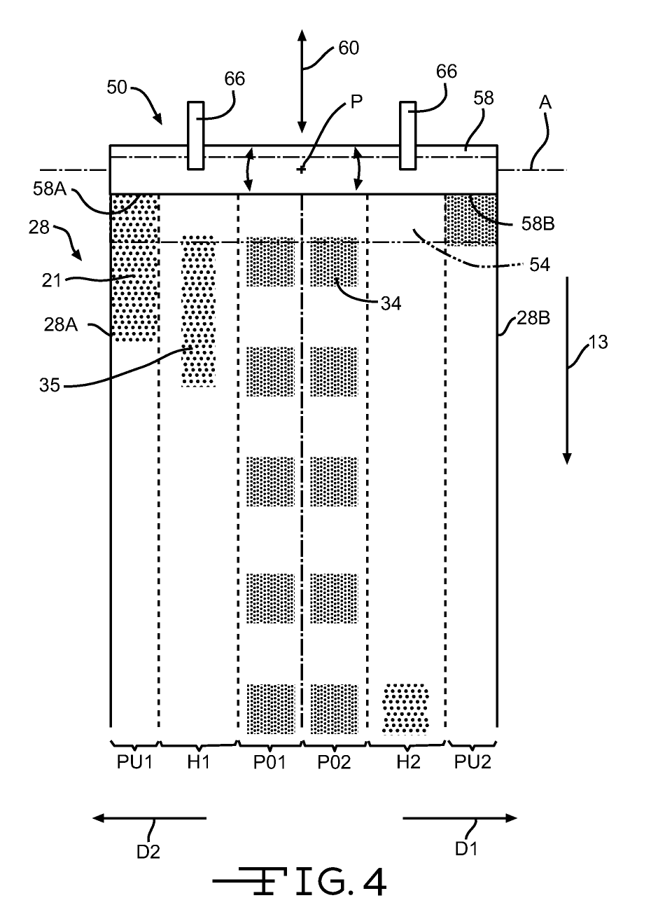

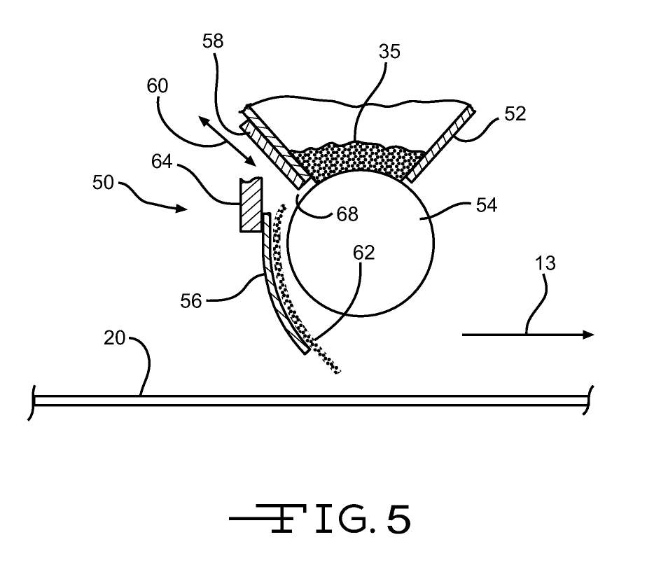

Referring now to FIGS. 4, 5, and 6, a second embodiment of a tracking granule applicator is illustrated at 50. The tracking granule applicator 50 extends transversely across the granule-coated sheet 28 and defines an axis A. The tracking granule applicator 50 further includes a hopper 52. The hopper 52 is structured and configured to include compartments (not shown) which separate the headlap granules from the prime granules. The desired headlap and prime granules (in the embodiment illustrated in FIG. 5, headlap granules 35 are shown) are fed from the hopper 52 by a fluted roll 54 from which, upon rotation, the granules 35 are discharged into contact with a chute 56. A gate 58 is slidably mounted to the hopper 52 and movable in the direction of the arrow 60 for selectively releasing granules 35 into the chute 56.

If desired, the gate 58 may also be pivotally mounted relative to the hopper 52 about a pivot point P. Actuators or linkages 66 are connected to the gate 58 and move the gate 58 about the pivot point P, as will be described in detail below. The chute 56 guides the granules 35 outwardly and downwardly from the hopper 52 to the granule-coated sheet 28. As shown in FIG. 4, the gate 58 is in a first or normal operating position. In the first position, the first and second ends 58A and 58B of the gate 58 are substantially equidistant from the fluted roll 54.

The illustrated chute 56 is elongated and has a substantially curved cross-sectional shape. Alternatively, the chute 56 may have any other desired cross-sectional shape. The chute 56 guides the granules 35 forwardly, in the direction of the arrow 13 as the granules 35 move downwardly away from the hopper 52. As granules 35 exit the chute 56, the granules 35 define a substantially linear curtain of the granules 62 which engage the asphalt-coated sheet 20 within a desired lane, such as the lane H1 or H2, as best shown in FIG. 4. The fluted roll 54 may be driven by a drive motor (not shown).

The chute 56 directs the granules 35 onto the asphalt-coated sheet 20, such that the headlap granules are deposited into the headlap granule lanes H1 and H2, and the prime granules are deposited into the prime granule lanes PU1, PU2, PO1, and PO2. If desired, the chute 56 may be provided with side walls (not shown) to maintain separation of headlap and prime granules, such that the headlap granules 35 and prime granules 21 are deposited in their respective granule lanes H1, H2, and PU1, PU2, PO1, and PO2, relative to the granule-coated sheet 28. The chute 56 may be mounted to the apparatus 10 by any desired means, such as a mounting bracket 64.

In operation, the granule-coated sheet 28 may be manufactured as described above. When a sensor S detects undesirable lateral movement of the granule-coated sheet 28 as it moves across the slate drum 30, additional headlap granules 35 may be deposited on the headlap granule lanes H1 or the headlap granule lane H2. For example, if a sensor S determines that the granule-coated sheet 28 has moved laterally in a first direction (in the direction of the arrow D1 when viewing FIG. 3) relative to the slate drum 30, additional headlap granules 35 are deposited in the headlap granule lane H1. The granule-coated sheet 28 will therefore be slightly thicker in the headlap granule lane H1. As the granule-coated sheet 28 with the increased granule thickness in headlap granule lane H1, moves around the slate drum 30, the granule-coated sheet 28 will move, relative to the slate drum 30, toward the headlap granule lane H1 (in the direction of the arrow D2 when viewing FIG. 3).

The additional headlap granules 35 deposited in the headlap granule lane H1 may have a width W. In the illustrated embodiments, the width W of the additional headlap granules 35 is defined as any desired distance up to a maximum lateral distance that the additional headlap granules 35 may extend without contaminating, or being deposited within, the granule regions that will be exposed on a roof; i.e., the prime granule lanes PU1, PU2, PO1, and/or PO2.

The additional headlap granules 35 deposited in the headlap granule lane H1 may also have any desired thickness above a typical or pre-determined thickness of the granules retained on the granule-coated sheet 28 after the granule-coated sheet 28 has been turned around the slate drum 30 to press the granules into the asphalt coating. It will be understood that the additional headlap granules 35 deposited in the headlap granule lane H1 will fall off the upwardly facing surface of the granule-coated sheet 28 and into the hopper 32 after the granule-coated sheet 28 has been turned around the slate drum 30.

Referring again to FIGS. 2 and 3, the additional headlap granules 35 are deposited in the desired headlap granule lane H1 or H2 by the first embodiment of the tracking granule applicator 24 mounted above the lane H1 or H2 to which additional headlap granules 35 will be deposited.

For example, when a sensor S detects undesirable lateral movement of the granule-coated sheet 28 across the slate drum 30 in the direction of the arrow D1, additional granules may be deposited on the headlap granule lane H1 from the tracking granule applicator 24 mounted above the lane H1. When the granule-coated sheet 28 has returned to its desired lateral position relative to the slate drum 30, the tracking granule applicator 24 will close such that additional headlap granules 35 are no longer deposited in the headlap granule lane H1. Alternatively, at least some additional granules may be substantially continuously deposited onto the granule-coated sheet 28 by either the tracking granule applicator 24 mounted above the lane H1 or the tracking granule applicator 24 mounted above the lane H2 to maintain the granule-coated sheet 28 in a desired lateral position relative to the slate drum 30.

Referring again to FIGS. 4, 5, and 6, additional prime granules 21 and/or headlap granules 35 may deposited in the desired headlap granule lane H1 or H2, or underlay prime granule lanes PU1 or PU2, respectively, by the second embodiment of the tracking granule applicator 50.

For example, when a sensor S detects undesirable lateral movement of the granule-coated sheet 28 across the slate drum 30 in the direction of the arrow D1, additional granules may be deposited on one or both of the underlay prime granule lane PU1 or the headlap granule lane H1. The granule-coated sheet 28 will therefore be slightly thicker in one or both of the underlay prime granule lane PU1 and the headlap granule lane H1. The linkages 66 urge a selected portion of the gate 58 away from the fluted roll 54 such that one end of the gate 58 creates a slightly larger opening 68 between the gate 58 and the fluted roll 54. In the illustrated embodiment, a first end 58A of the gate 58 is moved away from the fluted roll 54 to create a slightly larger opening 68 between the first end 58A of the gate 58 and the fluted roll 54.

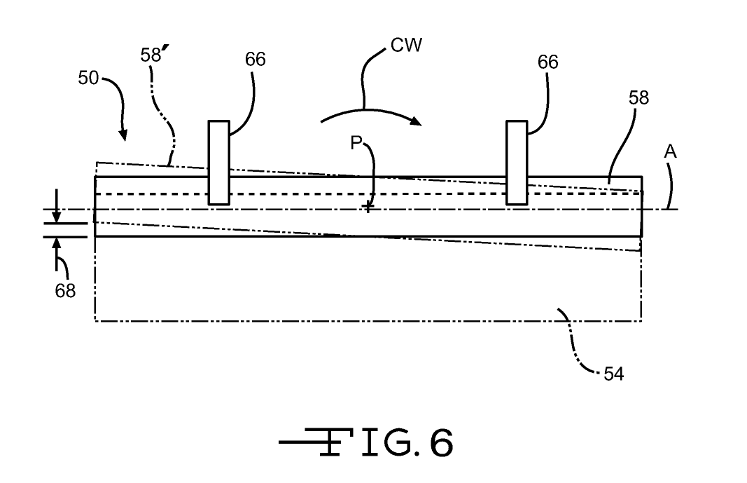

In another embodiment, the gate 58 may be pivoted slightly in the direction of the arrow CW (in a clockwise direction when viewing FIG. 6) about the pivot point P, as shown by the phantom line 58′ in FIG. 6. The linkages 66 urge the gate 58 such that the gate 58 is pivoted slightly in the direction of the arrow CW (in a clockwise direction when viewing FIG. 6) about the pivot point P, as shown by the phantom line 58′ in FIG. 6.

Such clockwise pivoting movement of the gate 58 creates a slightly larger opening 68 between a first end 58A of the gate 58 and the fluted roll 54. The opening 68 defines a flow path for granules at the first end 58A of the gate 58 within the hopper 52. One or both of additional prime granules 21 or headlap granules 35 are then deposited in the underlay prime granule lane PU1 or the headlap granule lane H1, respectively. The granule-coated sheet 28 will therefore be slightly thicker in one or both of the underlay prime granule lane PU1 and the headlap granule lane H1.

When the granule-coated sheet 28 has returned to its desired lateral position relative to the slate drum 30, the linkages 66 will urge the gate 58 slightly such that the gate 58 is pivoted in a counter-clockwise direction about the pivot point P, and back to the first position wherein the first and second ends 58A and 58B of the gate 58 are substantially equidistant from the fluted roll 54.

It will be understood that the tracking granule applicator 50 described above is not required, and that any other desired granule dispenser having a slidable and/or pivotable gate may be provided.

The present invention should not be considered limited to the specific examples described herein, but rather should be understood to cover all aspects of the invention. Various modifications, equivalent processes, as well as numerous structures and devices to which the present invention may be applicable will be readily apparent to those of skill in the art. Those skilled in the art will understand that various changes may be made without departing from the scope of the invention, which is not to be considered limited to what is described in the specification.

What is claimed is:

1. A method for adjusting the track of a granule-coated sheet, the method comprising:
moving a granule-coated sheet around a drum, the granule-coated sheet including first granules;
sensing a track of the granule-coated sheet at the drum;
generating a first signal when the granule-coated sheet has moved off a pre-designated track; and
applying second granules to a lane portion of the granule-coated sheet prior to the drum in response to the first signal;
wherein the second granules make the granule-coated sheet thicker in the lane portion relative to a thickness of the granule-coated sheet outside the lane portion.

2. The method according to claim 1, further including the step of discharging the first granules from at least one granule dispenser on to an asphalt-coated sheet to define the granule-coated sheet.

3. The method according to claim 1, further including the step of pressing the first granules into a first surface of the granule-coated sheet as the granule-coated sheet moves around the drum.

4. The method according to claim 1, wherein the lane portion of the granule-coated sheet is a headlap granule lane.

5. The method according to claim 4, wherein the second granules are headlap granules.

6. The method according to claim 1, wherein the second granules are headlap granules.

7. The method according to claim 1, wherein the step of sensing a track of the granule-coated sheet at the drum includes identifying a first lateral direction in which the granule-coated sheet has moved relative to the pre-designated track.

8. The method according to claim 7, wherein the step of applying the second granules to a lane portion of the granule-coated sheet includes applying the second granules to a lane portion located in a longitudinal half of the granule-coated sheet in a second lateral direction opposite the first lateral direction in which the granule-coated sheet has moved.

9. The method according to claim 7, further including moving the granule-coated sheet with the second granules applied around the drum.

10. The method according to claim 9, wherein the granule-coated sheet with the second granules applied moves laterally relative to the drum in a direction toward the lane portion having the second granules.

11. The method according to claim 1, wherein the second granules are applied to the lane portion by a tracking granule applicator.

12. A granule applicator comprising:
a granule hopper defining a granule outlet; and
a gate movably mounted relative to the hopper;
wherein the gate is movable between a plurality of first open positions wherein granules may flow out of the granule outlet; and
wherein the gate is also pivotally movable relative to the granule hopper between any of the plurality of first open positions and a plurality of pivoted positions.

13. The granule applicator according to claim 12, wherein in the pivoted positions the granule outlet is larger at one of the first and the second longitudinal ends of the gate than at the other of the longitudinal ends of the gate, and wherein the longitudinal end of the gate at which the granule outlet is larger defines an increased flow path for granules within the hopper.

14. A method for adjusting the track of a granule-coated sheet, the method comprising:
discharging granules from a granule dispenser on to an asphalt-coated sheet to define a granule-coated sheet;
moving the granule-coated sheet around a drum;
sensing a track of the granule-coated sheet at the drum;
generating a first signal when the granule-coated sheet has moved off a pre-designated track; and
increasing the amount of granules discharged from the granule dispenser on to a lane portion of the granule-coated sheet in response to the first signal;
wherein the increased amount of granules make the granule-coated sheet thicker in the lane portion relative to a thickness of the granule-coated sheet outside the lane portion.

15. The method according to claim 14, wherein the lane portion of the granule-coated sheet is a headlap granule lane.

16. The method according to claim 15, wherein the second granules are headlap granules.

17. The method according to claim 14, wherein the step of sensing a track of the granule-coated sheet at the drum includes identifying a first lateral direction in which the granule-coated sheet has moved relative to the pre-designated track.

18. The method according to claim 17, wherein the step of increasing the amount of granules discharged from the granule dispenser to a lane portion of the granule-coated sheet includes applying the increased amount of granules to a lane portion located in a longitudinal half of the granule-coated sheet in a second lateral direction opposite the first lateral direction in which the granule-coated sheet has moved.

19. The method according to claim 18, further including moving the granule-coated sheet with the increased amount of granules applied around the drum.

20. The method according to claim 19, wherein the granule-coated sheet with the increased amount of granules applied moves laterally relative to the drum in a direction toward the lane portion having the increased amount of granules.
